(19) United States
(12) Patent Application Publication
(10) Pub. No.: US 2013/0162283 A1
(43) Pub. Date: Jun. 27, 2013

(54) LUMINANCE TEST SYSTEM FOR LEDS

(71) Applicant: KANG-BIN WANG, Shenzhen City (CN)

(72) Inventor: KANG-BIN WANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/596,162

(22) Filed: Aug. 28, 2012

(30) Foreign Application Priority Data
Dec. 26, 2011 (CN) 201110441148.5

(51) Int. Cl. G01R 31/26

(52) U.S. Cl. 324/762.07

(57) ABSTRACT

A test system for Light-emitting diodes (LEDs) includes a microcontroller, a plurality of light sensors, a plurality of shielding members and a display module. Each of the plurality of light sensors is connected to the microcontroller and each of LEDs. Each of the plurality of light sensors is capable of detecting luminance of the plurality of LEDs respectively. Each of the plurality of shielding members is configured to prevent light outside of each of the plurality of shielding members from interfering with light emitted from each of the LEDs inside of each of the plurality of shielding members. The microcontroller is adapted to read light intensities sensed by the plurality of light sensors according to a predetermined sequence and send the light intensities to the display module to display the light intensities in the predetermined sequence.

### BACKGROUND

1. Technical Field

The present disclosure relates to luminance test systems, and particularly to a luminance test system for a plurality of LEDs.

2. Description of Related Art

Light-emitting diode (LED) is widely applied in many applications because of its high-luminance, low-energy, and long lifetime. Due to the difference in the optical properties of LED, a plurality of LEDs, each having a different light intensity, the display quality of the plurality of LEDS may be bad. Thus, before using the LED, intensity of LED will be tested by a test system. Typically, a test system includes a light sensor and a display. The light sensor detects a luminance of the LED, and the display displays the luminance value of the LED. However, the test system van only test one LED one at a time, and the efficiency of the test system is low.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of a test system according to an embodiment.

FIG. 2 illustrates a detailed circuit diagram of the test system of FIG. 1.

FIG. 3 is a schematic diagram of a shielding member.

FIG. 4 is similar to FIG. 3, but the shielding member receives a LED and a light sensor.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

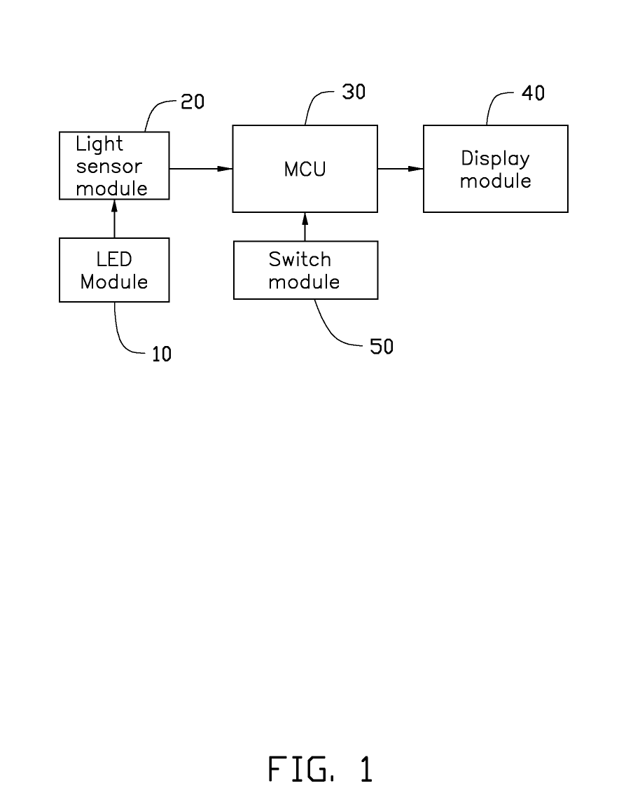

FIG. 1 shows a test system configured to detect a luminance of a LED module 10. The test system includes a light sensor module 20, a microcontroller (MCU) 30 connected to the light sensor module 20, a display module 40 connected to the MCU 30, a switch module 50 connected to the microcontroller 30, and a plurality of shielding members 60.

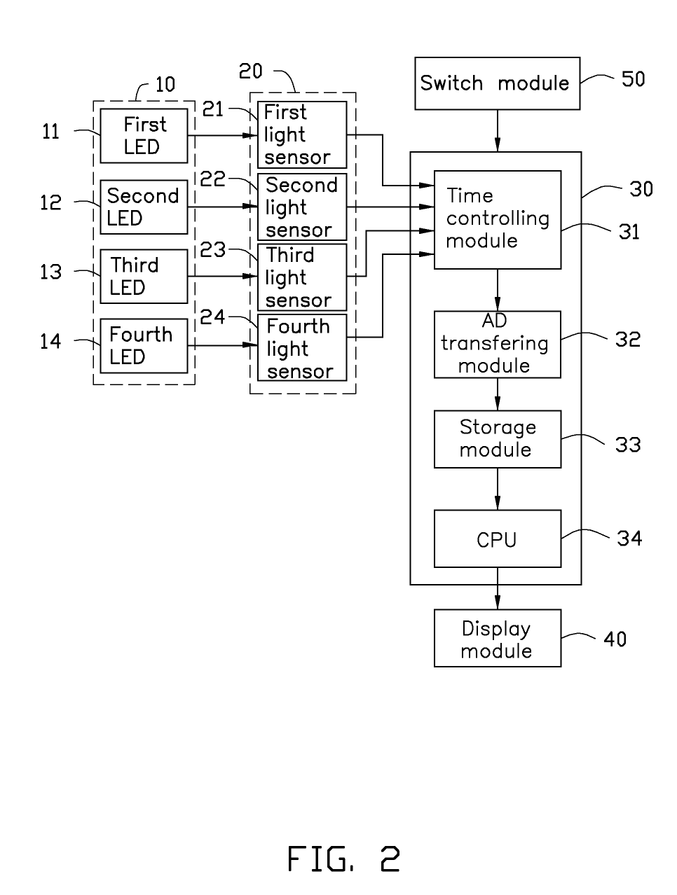

Referring to FIG. 2, the LED module 10 includes a plurality of LEDs, and the light sensor module 20 includes a plurality of light sensors according to the plurality of LEDs. In one embodiment, the LED module 10 includes a first LED 11, a second LED 12, a third LED 12, and a fourth LED 14. The light sensor module 20 includes a first light sensor 21, a second light sensor 22, a third light sensor 23, and a fourth light sensor 24. The first light sensor 21, the second light sensor 22, a third light sensor 23, and the fourth light sensor 24 are configured to detect a luminance of the first LED 11, the second LED 12, the third LED 13, and the fourth LED 13 respectively.

The MCU 30 includes a time controlling module 31, a analog to digital (AD) transferring module 32 connected to the time controlling module 31, a storage module 33, and a Central Processing Unit (CPU) 34. The first light sensor 21, the second light sensor 22, the third light sensor 23, and the fourth light sensor 24 are connected to the time controlling module 31 respectively via a signal line 210 and configured to sense a analogue light intensity of the first LED 11, the second LED 12, the third LED 13, and the fourth LED 14 respectively. The time controlling module 31 in turn transmits the analogue light intensities to the AD transferring module 32 according to a predetermined sequence, for preventing the analogue light intensities mutual interference. The AD transferring module 32 transfers the analogue light intensities to digital light intensities in the predetermined sequence and saves the digital light intensities to the storage module 33. The storage module 33 saves the digital light intensities to addresses. The CPU reads the digital light intensity according to the corresponding address and display the corresponding LED and the digital light intensity on the display module 40.

The switch module 50 includes a plurality of switches. Each of the plurality of switches controls each of the plurality of LEDs. In one embodiment, the plurality of switches includes a first switches, a second switches, a third switches, and a fourth switch corresponding to the first LED 11, the second LED 12, the third LED 13, and the fourth LED 14 respectively. When testing the first LED 11 and the second LED 12, the first switch and the second switch are switched on, and the third switch and the fourth switch are switched off. The MCU 30 reads light intensities of the first LED 11 and the second LED 12, while no light intensities of the third LED 13 and the fourth LED 14 are read.

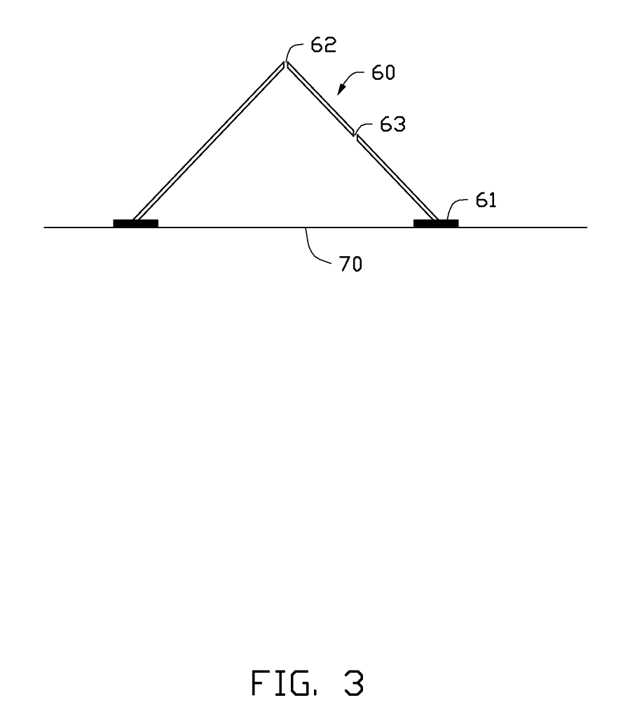

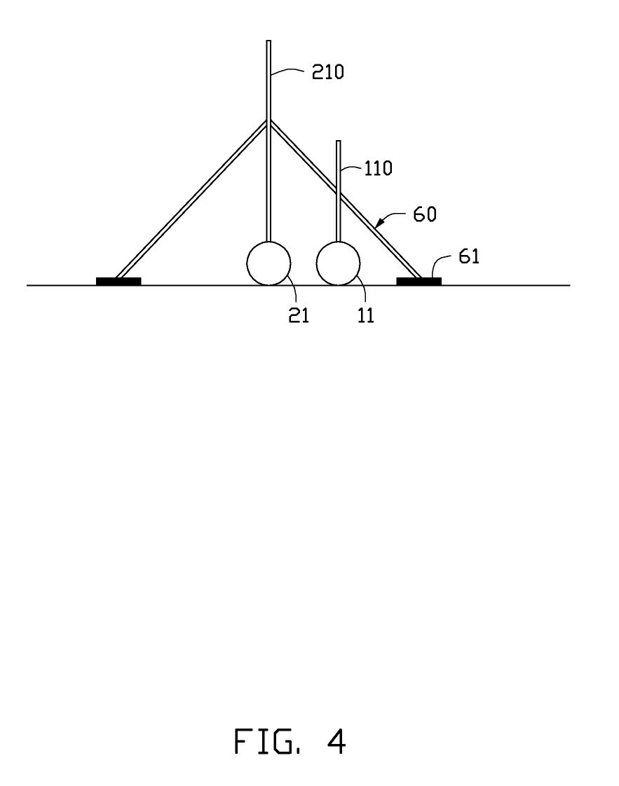

Referring to FIGS. 3-4, each of the plurality of shielding members 60 is substantially taper-shaped. An absorbing plate 61 is located on bottom portion of each of the plurality of shielding members 60, for attaching the plurality of shielding members 60 on a smooth plane 70 (such as a desk or a wall). A first through hole 62 is defined in a top portion of each of the plurality of shielding members 60. A second through hole 63 is defined in a side portion of each of the plurality of shielding members 60. When the test system is testing light intensities of the LED module 10, the LED module 10 and the light sensor module 20 are placed in the plane 70. For example, when the test system is testing light intensities of the first LED 11, the first LED 11 and the first light sensor 21 are placed in the plane 70. The signal line, connected to the first sensor light 21, extends through the first through hole 62 of each of the plurality of shielding members 60 to expose out of each of the plurality of shielding members 60. The power wire 110, connected to the first LED 11, extends through the second through hole 63 to expose out of each of the plurality of shielding members 60. The absorbing plate 61 of each of the plurality of shielding members 60 is attached on the plane 70. The first LED 11 and the first light sensor 21 are thereby accommodated in each of the plurality of shielding members 60. In one embodiment, a diameter of the signal line 210 is substantially equal to a diameter of the first through hole 62, and a diameter of the power wire 110 is substantially equal to a diameter of the second through hole 63. The signal line 210 is configured to jam the first through hole 62, and the power wire 110 is configured to chink the second through hole 63 to close each of the plurality of shielding members 60, for preventing light out of each of the plurality of shielding members 60 from interfering light emitted from the first LED 11. The light intensity sensed by the first light sensor 21 is transferred to the MCU 30 by the signal line 210, and the power wire 110 is connected to a power supply (not shown), for supplying working voltage to the first LED 11. In one embodiment, each of the plurality of shielding members 60 can be other shapes and is made of opaque material.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A test system for light-emitting diodes (LEDs) comprising:
a microcontroller;
a plurality of light sensors, each of the plurality of light sensors being connected to the microcontroller and each of the LEDs;
a plurality of shielding members, each of the plurality of shielding members being configured to receive each the plurality of light sensors and each of the LEDs connected to each of the plurality of light sensors; and
a display module;
wherein each of the plurality of light sensors is connected to each of the LEDs and capable of detecting luminance of each of the LEDs; each of the plurality of shielding members is configured to prevent light outside of each of the plurality of shielding members from interfering with light emitted from each of the LEDs inside of each of the plurality of shielding members; the microcontroller is adapted to read light intensities sensed by the plurality of light sensors according to a predetermined sequence and send the light intensities to the display module to display the light intensities in the predetermined sequence.

2. The test system for LEDs of claim 1, wherein the microcontroller comprises a time controlling module, each of the plurality of light sensors is connected to the time controlling module, and the time controlling module is configured to control a transmitting sequence of output signals outputted by the plurality of light sensors.

3. The test system for LEDs of claim 2, wherein the microcontroller further comprises an analog to digital (AD) transferring module connected to the time controlling module, and the AD transferring module transfers analogue light intensities outputted by the plurality of light sensor to digital light intensities according to the predetermined sequence.

4. The test system for LEDs of claim 3, wherein the microcontroller further comprises a storage module connected to the AD transferring module, and the storage module saves each of the digital light intensities outputted by the AD transferring module to an address.

5. The test system for LEDs of claim 4, wherein the microcontroller comprises a central processing unit (CPU) connected to the storage module, the CPU reads a digital light intensities of the digital light intensities according to the address and display the digital light intensity and the LED detected by one of the plurality of light sensors.

6. The test system for LEDs of claim 1, wherein each of the plurality of light sensors is connected to the microcontroller by a signal line, each of the plurality of shielding members defines a first through hole, and the signal line extends through the first through hole.

7. The test system for LEDs of claim 6, further comprising a plurality of power wires, wherein each of the plurality of power wires is connected to each of the LEDs, each of the plurality of shielding members further defines a second through hole, and each of the plurality of power wires extends through each of the second through hole.

8. The test system for LEDs of claim 7, wherein a diameter of each of the plurality of power lines is substantially equal to a diameter of each of the second through hole.

9. The test system for LEDs of claim 1, wherein each of the plurality of shielding members is substantially taper-shaped.

10. The test system for LEDs of claim 1, further comprising an absorbing plate on each of the plurality of shielding members, and the absorbing plate is configured to be attached on a plane.

11. The test system for LEDs of claim 1, further comprising a switch module, wherein the switch module comprises a plurality of switches, and each of the plurality of switches is connected to each of the LEDs to switch on power the LEDs; the microcontroller reads light intensities of the LEDs when each of the plurality of switches is switched on.

12. A test system for light-emitting diodes LEDs comprising:
a microcontroller, the microcontroller comprising a time controlling module;
a plurality of light sensors, each of the plurality of light sensors being connected to controlling module and each of LEDs;
a plurality of shielding members, each of the plurality of shielding members being configured to receive each the plurality of light sensors and each of the LEDs connected to each of the plurality of light sensors; and
a display module;
wherein each of the plurality of light sensors is capable of detecting luminance of each of the LEDs; each of the plurality of shielding members is configured to preventing light outside each of the shielding members interfering light emitted from each of the LEDs inside of each of the plurality of shielding members; the microcontroller is adapted to read light intensities sensed by the plurality of light sensors according to a predetermined sequence and send the light intensities to the display module to display the light intensities in the predetermined sequence.

13. The test system for LEDs of claim 12, wherein the microcontroller further comprises an analog to digital (AD) transferring module connected to the time controlling module, and the AD transferring module transfers analogue light intensities outputted by the plurality of light sensor to digital light intensities according to the predetermined sequence.

14. The test system for LEDs of claim 13, wherein the microcontroller further comprises a storage module connected to the AD transferring module, and the storage module saves each of the digital light intensities outputted by the AD transferring module to an address.

15. The test system for LEDs of claim 13, wherein the microcontroller comprises a processing unit (CPU) connected to the storage module, the CPU reads a digital light intensity according to the corresponding address and display the digital light intensity and the LED.

16. The test system for LEDs of claim 11, wherein each of the plurality of light sensors is connected to the microcontroller by a signal line, each of the plurality of shielding members defines a first through hole, and the signal line extends through the first through hole.

17. The test system for LEDs of claim 15, further comprising a plurality of power wires, wherein each of the plurality of power wires is connected to each of the LEDs, each of the plurality of shielding members further defines a second through hole, and each of the plurality of power wires extends through the second through hole.

18. The test system for LEDs of claim 16, wherein a diameter of each of the plurality of power lines is substantially equal to a diameter of the second through hole. Page 11 of 13

19. The test system for LEDs of claim 11, wherein each of the plurality of shielding members is substantially taper-shaped.

20. The test system for LEDs of claim 11, further comprising an absorbing plate on each of the plurality of shielding members, and the absorbing plate is configured to be attached on a plane.
